(19) United States
(12) Patent Application Publication
(10) Pub. No.: US 2026/0012141 A1
(43) Pub. Date: Jan. 8, 2026

(54) LINEARIZATION METHOD FOR POWER AMPLIFIER AND ELECTRONIC DEVICE THEREOF USING NEURAL NETWORK

(71) Applicant: LITE-ON TECHNOLOGY CORPORATION, TAIPEI CITY (TW)

(72) Inventors: Wen Chieh CHEN, Taipei City (TW); Bo-Heng LI, Taipei City (TW)

(21) Appl. No.: 19/254,379

(22) Filed: Jun. 30, 2025

Related U.S. Application Data
(60) Provisional application No. 63/666,813, filed on Jul. 2, 2024.

(51) Int. Cl. H03F 1/32; G06N 3/08; H03F 3/24

(52) U.S. Cl. CPC H03F 1/3247; G06N 3/08; H03F 3/245

(57) ABSTRACT

A linearization method for a power amplifier includes the following steps. An input signal and an error associated with the input signal are received. The input signal and the error are input into a neural network model. A first intermediate signal is generated using the neural network model. The first intermediate signal is input into a power amplifier, so that the power amplifier outputs a first output signal. The first output signal is fed back into an inverse model of an ideal power amplifier, so that the inverse model outputs a second output signal. The difference between the first intermediate signal and the second output signal is calculated to obtain the error.

### CROSS REFERENCE TO RELATED APPLICATIONS

This application claims the benefit of U.S. provisional application No. 63/666,813, filed on Jul. 2, 2024, the entirety of which are incorporated by reference herein.

### BACKGROUND OF THE DISCLOSURE

### Field of the Disclosure

The disclosure relates to a power amplifier, and, in particular, it relates to a linearization method for a power amplifier and an electronic device thereof.

### Description of the Related Art

In the prior art, Digital Pre-Distortion (DPD) is used to perform linearization of power amplifiers (PA). DPD works by pre-distorting transmitted data in the digital domain to remove distortions caused by PA compression in the analog domain. In this way, DPD can double, or more than double, the PA power-added efficiency, driving the PA further into saturation while meeting linearity requirements.

However, since the inverse function of the nonlinear components in the input and output curves of a power amplifier needs to be calculated during the DPD process, the calculation process is very long and complicated, and it requires huge computing resources. Therefore, how to simplify the linearization operation of a power amplifier has become an important issue.

### BRIEF SUMMARY OF THE DISCLOSURE

An embodiment of the disclosure provides a linearization method for a power amplifier. The linearization method includes the following steps. An input signal and an error associated with the input signal are received. The input signal and the error are input into a neural network model. A first intermediate signal is generated using the neural network model. The first intermediate signal is input into a power amplifier, so that the power amplifier outputs a first output signal. The first output signal is fed back into an inverse model of an ideal power amplifier, so that the inverse model outputs a second output signal. The difference between the first intermediate signal and the second output signal is calculated to obtain the error.

According to the linearization method described above, the neural network model includes a plurality of neural network nodes. The step of generating the first intermediate signal using the neural network model includes the following steps. An input value is provided to each neural network node. The output value is calculated by each neural network node according to the input value, the error and a plurality of weights. The output value is provided to other neural network node as an input value. The input signal is the input value of one of the neural network nodes.

According to the linearization method described above, the inverse model of the ideal power amplifier is equal to an inverse function of the linear components of the power amplifier.

The linearization method further includes filtering the error.

According to the linearization method described above, the training process of the neural network model includes the following steps. A training signal is input into the neural network model and the ideal power amplifier, so that the ideal power amplifier outputs a second intermediate signal. The second intermediate signal is input into a gain saturator, so that the gain saturator outputs a third intermediate signal. The difference between the third intermediate signal and the first output signal is calculated to obtain a loss value. The loss value is a square of the difference between the third intermediate signal and the first output signal. The loss value is partially differentiated and multiplied by a learning rate to update the weights.

An embodiment of the disclosure also provides an electronic device. The electronic device includes a processor and a power amplifier. The processor includes a subtractor and an inverse model of an ideal power amplifier. The subtractor generates an error. The processor receives an input signal wherein the error is associated with the input signal, inputs the input signal and the error into a neural network model, and generates a first intermediate signal using the neural network model. The power amplifier is electrically connected to the processor. The processor receives the first intermediate signal, outputs a first output signal, and feeds the first output signal back into the inverse model, so that the inverse model outputs a second output signal. The subtractor outputs the difference between the first intermediate signal and the second output signal to obtain the error.

According to the electronic device described above, the neural network model includes a plurality of neural network nodes. The step of generating the first intermediate signal using the neural network model includes the following steps. The neural network model provides an input value to each neural network node. Each neural network node calculates an output value according to the input value, the error and a plurality of weights. Each neural network provides the output value to other neural network node as an input value. The input signal is the input value of one of the neural network nodes.

According to the electronic device described above, the inverse model of the ideal power amplifier is equal to an inverse function of the linear components of the power amplifier.

The electronic device further includes a filter. The filter filters the error.

According to the electronic device described above, the training process of the neural network model includes the following steps. The processor inputs a training signal into the neural network model and the ideal power amplifier, so that the ideal power amplifier outputs a second intermediate signal. The processor inputs the second intermediate signal into a gain saturator, so that the gain saturator outputs a third intermediate signal. The processor calculates the difference between the third intermediate signal and the first output signal to obtain a loss value. The loss value is a square of the difference between the third intermediate signal and the first output signal. The processor partially differentiates the loss value and multiplies the loss value by a learning rate to update the weights.

### BRIEF DESCRIPTION OF THE DRAWINGS

The disclosure can be more fully understood by reading the subsequent detailed description and examples with references made to the accompanying drawings.

FIG. 1 is a flow chart of a linearization method for a power amplifier in accordance with some embodiments of the disclosure.

FIG. 2 is a training flow chart of a neural network model in accordance with some embodiments of the disclosure.

FIG. 3 is a schematic diagram of an electronic device 300 in accordance with some embodiments of the disclosure.

FIG. 4 is a training schematic diagram of a neural network model 403 in an electronic device 400 in accordance with some embodiments of the disclosure.

### DETAILED DESCRIPTION OF THE EXEMPLARY EMBODIMENTS

In order to make the above purposes, features, and advantages of some embodiments of the disclosure more comprehensible, the following is a detailed description in conjunction with the accompanying drawing.

Certain terms are used throughout the description and following claims to refer to particular components. As one skilled in the art will understand, electronic equipment manufacturers may refer to a component by different names. This document does not intend to distinguish between components that differ in name but not function. It is understood that the words “comprise”, “have” and “include” are used in an open-ended fashion, and thus should be interpreted to mean “include, but not limited to . . . ”. Thus, when the terms “comprise”, “have” or “include” used in the disclosure are used to indicate the existence of specific technical features, values, method steps, operations, units or components. However, it does not exclude the possibility that more technical features, numerical values, method steps, work processes, units, components, or any combination of the above can be added.

The directional terms used throughout the description and following claims, such as: “on”, “up”, “above”, “down”, “below”, “front”, “rear”, “back”, “left”, “right”, etc., are only directions referring to the drawings. Therefore, the directional terms are used for explaining and not used for limiting the disclosure. Regarding the drawings, the drawings show the general characteristics of methods, structures, or materials used in specific embodiments. However, the drawings should not be construed as defining or limiting the scope or properties encompassed by these embodiments. For example, for clarity, the relative size, thickness, and position of each layer, each area, or each structure may be reduced or enlarged.

When the corresponding component such as layer or area is referred to as being “on another component”, it may be directly on this other component, or other components may exist between them. On the other hand, when the component is referred to as being “directly on another component (or the variant thereof)”, there is no component between them. Furthermore, when the corresponding component is referred to as being “on another component”, the corresponding component and the other component have a disposition relationship along a top-view/vertical direction, the corresponding component may be below or above the other component, and the disposition relationship along the top-view/vertical direction is determined by the orientation of the device.

It should be understood that when a component or layer is referred to as being “connected to” another component or layer, it can be directly connected to this other component or layer, or intervening components or layers may be present. In contrast, when a component is referred to as being “directly connected to” another component or layer, there are no intervening components or layers present.

The electrical connection or coupling described in this disclosure may refer to direct connection or indirect connection. In the case of direct connection, the endpoints of the components on the two circuits are directly connected or connected to each other by a conductor line segment, while in the case of indirect connection, there are switches, diodes, capacitors, inductors, resistors, other suitable components, or a combination of the above components between the endpoints of the components on the two circuits, but the intermediate component is not limited thereto.

The words “first”, “second”, and “third” are used to describe components. They are not used to indicate the priority order of or advance relationship, but only to distinguish components with the same name.

It should be noted that the technical features in different embodiments described in the following can be replaced, recombined, or mixed with one another to constitute another embodiment without depart in from the spirit of the disclosure.

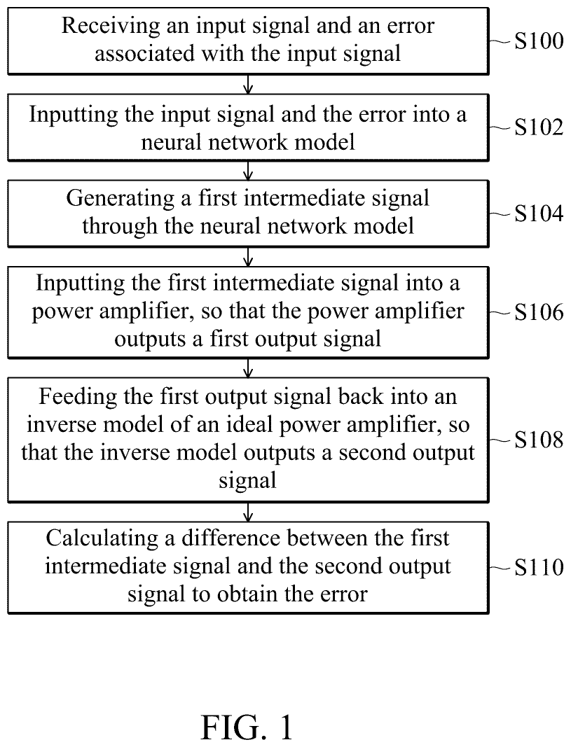

FIG. 1 is a flow chart of a linearization method for a power amplifier in accordance with some embodiments of the disclosure. As shown in FIG. 1, the linearization method for the power amplifier of the disclosure includes the following steps. An input signal and an error associated with the input signal are received (step S100). The input signal and the error are input into a neural network model (step S102). A first intermediate signal is generated using the neural network model (step S104). The first intermediate signal is input into a power amplifier, so that the power amplifier outputs a first output signal (step S106). The first output signal is fed back into an inverse model of an ideal power amplifier, so that the inverse model outputs a second output signal (step S108). The difference between the first intermediate signal and the second output signal is calculated to obtain the error (step S110). In some embodiments, after finishing step S110, the linearization method for the power amplifier of the disclosure filters the error.

The input signal in step S100 is an original signal that the power amplifier is expected to transmit. Since the power amplifier has characteristics of nonlinear components or interference, the linearization method for the power amplifier of the disclosure generates a first intermediate signal using a neural network model and inputs the first intermediate signal to the power amplifier for amplification, so as to reduce the signal distortion caused by the characteristics of the nonlinear components for the power amplifier. In some embodiments, the input signal is a radio frequency (RF) signal, but the disclosure is not limited thereto. In step S100, the error is the difference between the first intermediate signal and the second output signal in step S110. In some embodiments, the error may be the error that is filtered. In some embodiments, the error represents the nonlinear components or interference of the power amplifier. In step S102, the neural network model may be, for example, a convolution neural network (CNN), but the disclosure is not limited thereto.

In step S104, the neural network model generates the first intermediate signal according to the input signal and the error. The neural network model may include a plurality of neural network nodes. Each neural network node has a plurality of weights and receives an input value. One of the neural network nodes calculates an output value and provides the output value to other neural network node as an input value. The input value of one of the neural network nodes is the aforementioned input signal.

In some embodiments, step S104 includes the following steps. An input value is provided to each neural network node. The output value is calculated by each neural network node according to the input value, the error and a plurality of weights. The output value is provided to other neural network node as an input value. The input signal is the input value of one of the neural network nodes. The neural network model includes an output layer. The output layer includes a portion of neural network nodes of the neural network nodes. The neural network model generates the first intermediate signal according to the weights, the input values and the errors of the portion of neural network nodes in the output layer.

In step S106, the linearization method for the power amplifier of the disclosure inputs the first intermediate signal into the power amplifier. The power amplifier amplifies the first intermediate signal to output a first output signal. In some embodiments, the first output signal includes linear components and the nonlinear components of the power amplifier.

In step S108, the linearization method for the power amplifier of the disclosure calculates the inverse model of the ideal power amplifier. In some embodiments, the inverse model of the ideal power amplifier is equal to an inverse function of the linear components of the power amplifier. Afterwards, the linearization method for the power amplifier of the disclosure feeds the first output signal back into the inverse model of the ideal power amplifier, so that the inverse model outputs the second output signal.

In step S110, the linearization method for the power amplifier of the disclosure obtains the error by subtracting the second output signal from the first intermediate signal. In detail, since the first output signal includes the linear components and the nonlinear components of the power amplifier, when the second output signal is subtracted from the first intermediate signal, the linear components in the first intermediate signal cancels out the linear components in the first output signal, leaving only the nonlinear components of the power amplifier. That is, the error represents the nonlinear components or interference of the power amplifier. In some embodiments, after the linearization method for the power amplifier of the disclosure filters the error through the filter, the linearization method for the power amplifier of the disclosure feeds the filtered error back to step S100 to complete a linearization operation of the power amplifier.

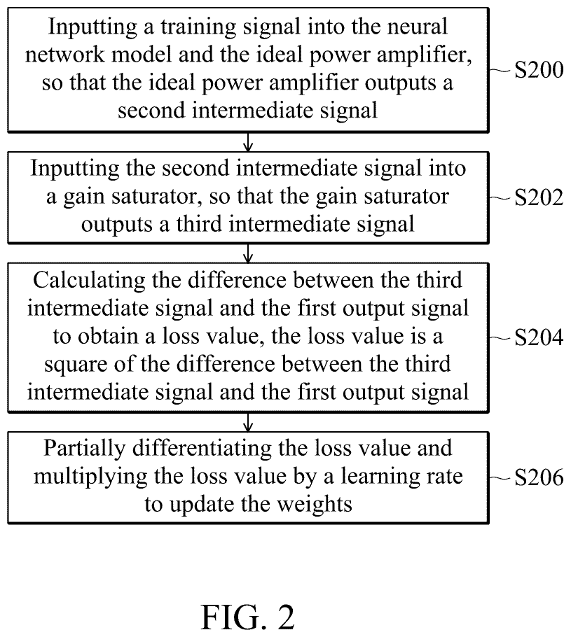

FIG. 2 is a training flow chart of a neural network model in accordance with some embodiments of the disclosure. As shown in FIG. 2, the linearization method for the power amplifier of the disclosure includes the following steps. A training signal is input into the neural network model and the ideal power amplifier, so that the ideal power amplifier outputs a second intermediate signal (step S200). The second intermediate signal is input into a gain saturator, so that the gain saturator outputs a third intermediate signal (step S202). The difference between the third intermediate signal and the first output signal is calculated to obtain a loss value. The loss value is a square of the difference between the third intermediate signal and the first output signal (step S204). The loss value is partially differentiated and multiplied by a learning rate to update the weights of each network node included in the neural network model (step S206).

In step S200, the linearization method for the power amplifier of the disclosure first calculates the linear components of the power amplifier in step S108 as the ideal power amplifier. Afterwards, the linearization method for the power amplifier of the disclosure then inputs the training signal into the ideal power amplifier to obtain a second intermediate signal. In step S202, the linearization method for the power amplifier of the disclosure first generates a gain saturator. In some embodiments, the gain saturator may be, for example, a digital gain saturator, but the disclosure is not limited thereto.

In step S204, the linearization method for the power amplifier of the disclosure subtracts the first output signal from the third intermediate signal to obtain the loss value. Finally, in step S206, the linearization method for the power amplifier of the disclosure partially differentiates the loss value and multiplies the loss value by a learning rate to update the weights of each network node included in the neural network model, so that the first intermediate signal output by the neural network model becomes more accurate after the training process.

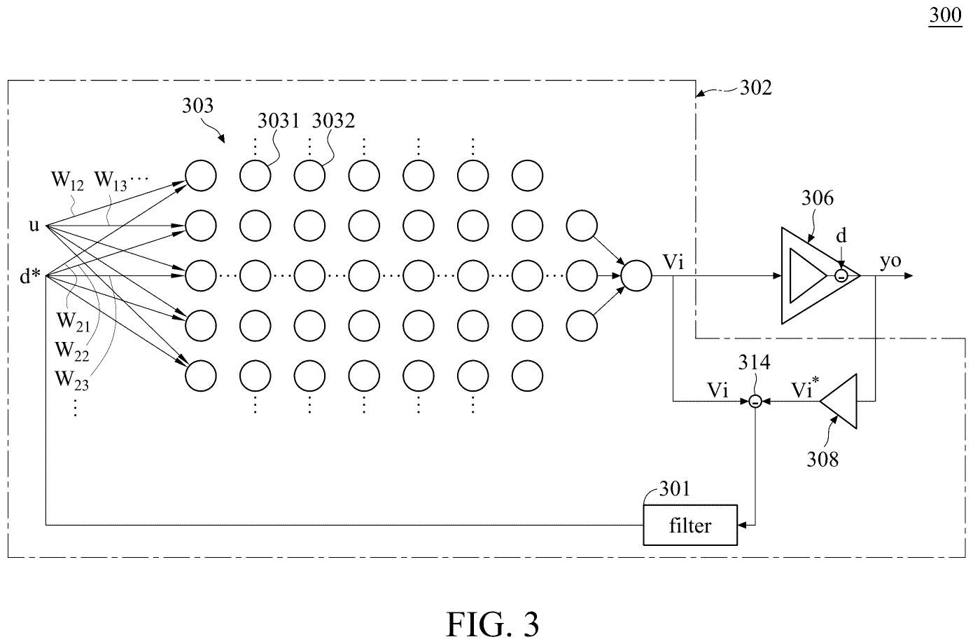

FIG. 3 is a schematic diagram of an electronic device 300 in accordance with some embodiments of the disclosure. As shown in FIG. 3, the electronic device 300 includes a processor 302 and a power amplifier 306. The processor 302 may include an inverse model 308 of the ideal power amplifier, a subtractor 314, and a filter 301. The processor 302 receives an input signal u. An error d* is associated with the input signal u. The processor 302 runs a neural network model 303. In some embodiments, the neural network model 303 includes a plurality of neural network nodes. The processor 302 inputs the input signal u and the error d* into the neural network model 303. The processor 302 generates a first intermediate signal Vi using the neural network model 303.

The power amplifier 306 is electrically connected to the processor 302. The power amplifier 306 receives the first intermediate signal Vi, amplifies the first intermediate signal Vi and outputs a first output signal yo. The processor 302 is connected to an output end of the power amplifier 306 and receives the first output signal yo. Therefore, the power amplifier 306 feeds the first output signal yo back into the inverse model 308, and the inverse model 308 outputs a second output signal Vi*. In some embodiments, the inverse model 308 of the ideal power amplifier is equal to an inverse function of the linear components of the power amplifier 306.

The subtractor 314 receives the first intermediate signal Vi and the second output signal Vi* and outputs the difference between the first intermediate signal Vi and the second output signal Vi* to obtain the error d*.

The filter 301 receives the error d* and filters the error d*. The filter 301 inputs the filtered error d* into the neural network model 303, so that the neural network model 303 generates the first intermediate signal Vi again.

In some embodiments, the processor 302 does not include the filter 301. Therefore, the subtractor 314 can directly input the error d* into the neural network model 303, so that the neural network model 303 generates the first intermediate signal Vi again.

The neural network model 303 includes a plurality of neural network nodes. Each neural network node calculates an output value according to an input value, the error d* and a plurality of weights. The neural network model 303 generates the first intermediate signal Vi through the calculation of each neural network node. In detail, the neural network model 303 includes a neural network node 3031. The neural network node 3031 receives an input value IN and calculates intermediate values INT1 and INT2 according to the input value IN, the error d* and weights w1, w2, w3 and w4. The intermediate value INT1 is equal to ReLU (IN×w1+d*×w2), and the intermediate value INT2 is equal to ReLU (IN×w3+d*×w4), wherein ReLU(x) is a linear rectified function (Rectified Linear Unit: ReLU). If x is less than 0 (x<0), ReLU(x)=0 is obtained. If x is greater than or equal to 0 (x≥0), ReLU(x)=x is obtained. Therefore, the intermediate value INT1 is greater than or equal to 0 (INT1≥0) and the intermediate value INT2 is greater than or equal to 0 (INT2>0). Next, the neural network node 3031 calculates the output value OUT according to the intermediate values INT1, INT2 and the weights w5, w6. The output value OUT is equal to ReLU (INT1×w5+INT2×w6). Therefore, the output value OUT is greater than or equal to 0 (OUT≥0).

The neural network node 3031 provides the output value OUT to other neural network node as the input value. For example, the neural network node 3031 provides the output value OUT to a neural network node 3032 as an input value. In other words, the input value OUT output by the neural network node 3031 becomes the input value IN of the neural network node 3032. The neural network node 3032 calculates the output value OUT according to the input value IN, the error d* and the weights in a similar manner as described above and provides the output value OUT to other neural network node.

The input value IN of parts of neural network nodes is the input signal u. For this portion of the neural network nodes, the intermediate value INT1 is equal to ReLU (u×w1+d*×w2), and the intermediate value INT2 is equal to ReLU (u×w3+d*×w4).

Another portion of neural network nodes are neural network output layer. The neural network output layer calculates and generates the first intermediate signals Vi according to multiple input values IN and multiple weights w. For example, if the output layer of the neural network receives three input values IN1, IN2, and IN3, the output layer can calculate the first intermediate signal Vi as (IN1×w7+IN2×w8+IN3×w9) based on weights w7, w8, and w9. The power amplifier 306 receives the first intermediate signal Vi, amplifies the first intermediate signal Vi and outputs the first output signal yo.

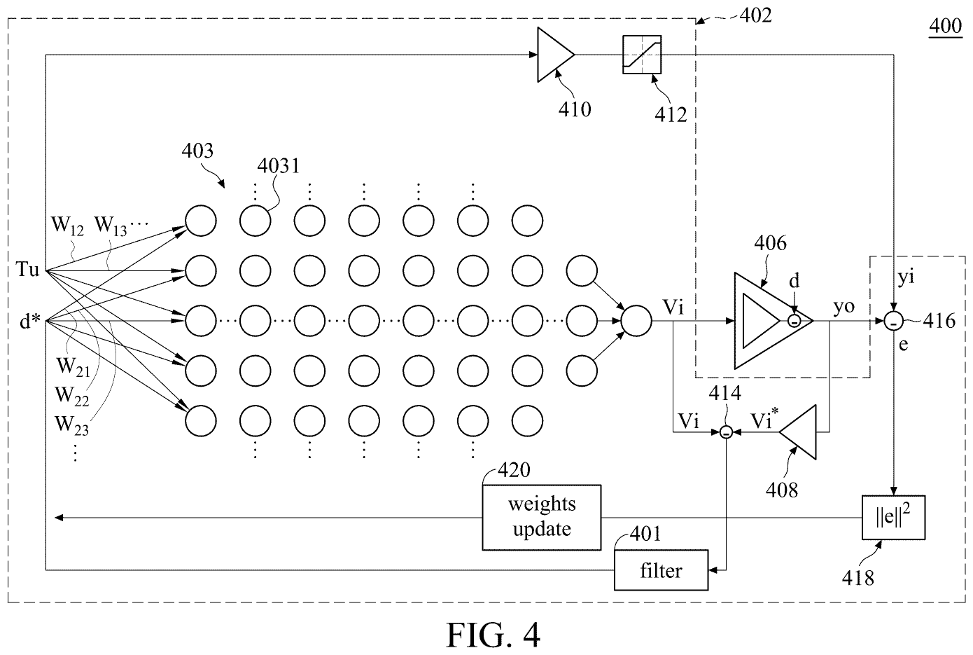

FIG. 4 is a training schematic diagram of a neural network model 403 in an electronic device 400 in accordance with some embodiments of the disclosure. The components of the electronic device 400 are very similar to those of the electronic device 300 in FIG. 3. For the corresponding components, please refer to the relevant description of FIG. 3. In FIG. 4, it can be seen that the processor 402 further includes an ideal power amplifier 410 and a gain saturator 412.

Through the training process, the processor 402 updates a plurality of weights (e.g., w1, w2, w3) of the neural network nodes in the neural network model 403. During the training process, the processor 402 does not receive the input signal u. The processor 402 receives a training signal Tu, which is a known signal. First, the processor 402 inputs the training signal Tu into the neural network model 403 and the ideal power amplifier 410. The ideal power amplifier 410 outputs the second intermediate signal, and the neural network model 403 generates the first intermediate signal Vi. The processor 402 inputs the second intermediate signal into the gain saturator 412, and the gain saturator 412 outputs a third intermediate signal yi.

The processor 402 calculates the difference between the third intermediate signal yi and the first output signal yo to obtain a loss value L. For example, the subtractor 416 calculates the difference between the third intermediate signal yi and the first output signal yo. The loss value L is the square of the difference between the third intermediate signal yi and the first output signal yo: L=∥e∥2, wherein e is the difference between the third intermediate signal yi and the first output signal yo. The processor 402 partially differentiates the loss value L and multiplies the loss value L by a learning rate N to update the plurality of weights of the neural network model 403. For example, for weight w1, the updated weight w1(n+1) is equal to w1(n)+N×(δ L/δ w1), wherein w1(n) is the weight w1 before update, N is the learning rate, and (δ L/δ w1) is the partial differential of the loss value L. The processor 402 continues to update the weights (for example, a weight update module 420). During the weight update process, if the loss value L is less than a predetermined value, the processor 402 stops the training process, so that the weight update is completed.

The linearization method for the power amplifier, the electronic device 300, and the electronic device 400 of the disclosure do not need to directly calculate the inverse function of the power amplifier as in the conventional Digital Pre-Distortion (PDP) method. The linearization method of the power amplifier of the disclosure directly regards the nonlinear components of the power amplifier as interference, so the inverse function of the power amplifier is directly calculated based on the ideal power amplifier, which greatly simplifies the difficulty of implementation.

The linearization method for the power amplifier, the electronic device 300, and the electronic device 400 of the disclosure regard all parts that are not as expected as internal interference or external interference, so even if there is really the external interference or the internal interference, it also can be resolved.

Once the neural network model 403 finishes training, the neural network model 403 can output the desired waveform very well, which means it can achieve the same function as the complex DPD with high efficiency.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A linearization method for a power amplifier, comprising:
receiving an input signal and an error associated with the input signal;
inputting the input signal and the error into a neural network model;
generating a first intermediate signal using the neural network model;
inputting the first intermediate signal into a power amplifier, so that the power amplifier outputs a first output signal;
feeding the first output signal back into an inverse model of an ideal power amplifier, so that the inverse model outputs a second output signal; and
calculating a difference between the first intermediate signal and the second output signal to obtain the error.

2. The linearization method as claimed in claim 1, wherein the neural network model comprises a plurality of neural network nodes, and the step of generating the first intermediate signal using the neural network model comprises:
providing an input value to each neural network node;
using each neural network node to calculate an output value according to the input value, the error and a plurality of weights; and
providing the output value to other neural network node as an input value;
wherein the input signal is the input value of one of the neural network nodes.

3. The linearization method as claimed in claim 1, wherein the inverse model of the ideal power amplifier is equal to an inverse function of linear components of the power amplifier.

4. The linearization method as claimed in claim 1, further comprising:
filtering the error.

5. The linearization method as claimed in claim 2, wherein a training process of the neural network model comprises:
inputting a training signal into the neural network model and the ideal power amplifier, so that the ideal power amplifier outputs a second intermediate signal;
inputting the second intermediate signal into a gain saturator, so that the gain saturator outputs a third intermediate signal;
calculating the difference between the third intermediate signal and the first output signal to obtain a loss value; wherein the loss value is a square of the difference between the third intermediate signal and the first output signal; and
partially differentiating the loss value and multiplying the loss value by a learning rate to update the weights.

6. An electronic device, comprising:
a processor, comprising:
a subtractor; and
an inverse model of an ideal power amplifier; wherein the subtractor is configured to generate an error; the processor is configured to receive an input signal wherein the error is associated with the input signal, input the input signal and the error into a neural network model, and generate a first intermediate signal using the neural network model; and
a power amplifier, electrically connected to the processor, configured to receive the first intermediate signal, output a first output signal, and feed the first output signal back into the inverse model, so that the inverse model outputs a second output signal;
wherein the subtractor is configured to output the difference between the first intermediate signal and the second output signal to obtain the error.

7. The electronic device as claimed in claim 6, wherein the neural network model comprises a plurality of neural network nodes, and the step of generating the first intermediate signal using the neural network model comprises:
the neural network model providing an input value to each neural network node; and
each neural network node calculating an output value according to the input value, the error and a plurality of weights, and providing the output value to other neural network node as an input value;
wherein the input signal is the input value of one of the neural network nodes.

8. The electronic device as claimed in claim 6, wherein the inverse model of the ideal power amplifier is equal to an inverse function of the linear components of the power amplifier.

9. The electronic device as claimed in claim 6, further comprising:
a filter, configured to filter the error.

10. The electronic device as claimed in claim 7, wherein the training process of the neural network model comprises:
the processor inputting a training signal into the neural network model and the ideal power amplifier, so that the ideal power amplifier outputs a second intermediate signal;
the processor inputting the second intermediate signal into a gain saturator, so that the gain saturator outputs a third intermediate signal;
the processor calculating the difference between the third intermediate signal and the first output signal to obtain a loss value; wherein the loss value is a square of the difference between the third intermediate signal and the first output signal; and
the processor partially differentiating the loss value and multiplying the loss value by a learning rate to update the weights.
